(19) United States
(12) Patent Application Publication
(10) Pub. No.: US 2010/0270919 A1
(43) Pub. Date: Oct. 28, 2010

(54) FLAT PLATE ENCAPSULATION ASSEMBLY FOR ELECTRONIC DEVICES

(76) Inventors: Matthew Dewey Hubert, Goleta, CA (US); James Daniel Tremel, Santa Barbara, CA (US); Kyle D. Frischknecht, Goleta, CA (US); Nugent Truong, Ventura, CA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 12/809,880

(22) PCT Filed: Dec. 20, 2008
(86) PCT No.: PCT/US08/87873

§ 371 Date: Jun. 21, 2010

Related U.S. Application Data
(60) Provisional application No. 61/015,802, filed on Dec. 21, 2007.

(51) Int. Cl. H01J 1/62; H05K 7/02

(52) U.S. Cl. 313/512; 174/260

(57) ABSTRACT

Described are encapsulation assemblies useful for electronic devices having a substrate and an active area, the encapsulation assembly comprising a barrier sheet and a barrier structure that contains an adhesive and a discreet material, wherein the barrier structure is configured so as to substantially hermetically seal an electronic device when in use thereon. The barrier structure bonds the encapsulation assembly to the electronic device and contains a getter material to protect against environmental degradation.

### RELATED APPLICATION

This application claims priority under 35 U.S.C. §119(e) from Provisional Application No. 60/015,802 filed on Dec. 21, 2007 which is incorporated by reference in its entirety.

### FIELD OF THE DISCLOSURE

This disclosure relates to encapsulation assemblies for electronic devices to prevent exposure of the electronic devices to environmental contaminants.

### BACKGROUND INFORMATION

Many electronic devices require protection from moisture, and in some cases oxygen, hydrogen, and/or organic vapors to prevent various types of degradation. Such devices include organic light-emitting diode (“OLED”) devices based on polymer or small molecule construction, microelectronic devices based on silicon IC technology, and MEMS devices based on silicon micro-machining. Exposure to the atmosphere can cause cathode degradation by oxide or hydroxide formation (leading to decreased performance/luminance), corrosion or stiction, respectively. Hermetic packaging and sealing technologies exist that address this problem, but these have limitations in performance lifetime and manufacturability, leading to high costs. The current technology uses cavity lids and a tape getter to protect electronic devices from moisture and oxygen permeation. The cost associated with creating a cavity in glass, along with placing getter material into each cavity is high. A low cost encapsulation technique is sought for electronic devices.

### SUMMARY OF THE DISCLOSURE

An encapsulation assembly for an electronic device, having a substrate and an active area, the encapsulation assembly comprising:

a generally planar barrier sheet; and

a barrier structure comprising an adhesive material and a discreet material, wherein:

the barrier structure is configured so as to substantially hermetically seal an electronic device when in use thereon to bond the encapsulation assembly to the device substrate; and wherein the barrier structure is configured so as to avoid direct contact with the electronic device substrate when the device is bonded to encapsulation assembly.

An encapsulation assembly for an electronic device, having a substrate, having a sealing structure and an active area, the encapsulation assembly comprising:

a barrier sheet having a substantially flat surface; and

a barrier structure containing an adhesive material and a discreet material,

a getter material; wherein:

the barrier structure is configured so as to substantially hermetically seal an electronic device when in use thereon; and wherein the barrier structure is configured to engage with the device substrate containing the getter material.

In the alternative, provided is an encapsulation assembly for an electronic device, having a substrate, having a barrier structure extending from the substrate and outside of an active area, the encapsulation assembly comprising a barrier sheet having a substantially flat surface; wherein the barrier sheet is configured to engage with the barrier structure on the device substrate.

The foregoing general description and the following detailed description are exemplary and explanatory only and are not restrictive of the invention, as defined in the appended claims.

### BRIEF DESCRIPTION OF THE DRAWINGS

The invention is illustrated by way of example and not limited in the accompanying figures.

FIG. 1 includes plan view of an electronic device.

FIG. 2 includes a cross-sectional view of the electronic device taken along line 2-2 in FIG. 1.

FIG. 3 includes another cross-section view of the electronic device shown in FIG. 1 and FIG. 2.

### DETAILED DESCRIPTION

The detailed description first addresses Definitions and Clarification of Terms followed by Electronic Device Structures.

### 1. Definitions and Clarification of Terms

Before addressing details of embodiments described below, some terms are defined or clarified. As used herein, the term “activating,” when referring to a radiation-emitting electronic component, is intended to mean providing proper signal(s) to the radiation-emitting electronic component so that radiation at a desired wavelength or spectrum of wavelengths is emitted.

The term “adhesive” is intended to mean a solid or liquid substance that is capable of holding materials by surface attachment. Examples of adhesives include, but are not limited to, materials that are organic and inorganic, such as those using ethylene vinyl acetates, phenoylic resins, rubber (nature and synthetic), carboxylic polymers, polyamides, polyimides, styrene-butadiene, silicone, epoxy, urethane, acrylic, isocynoate, polyvinyl acetates, polyvinyl alcohols, polybenzimidazole, cement, cyanoacrylate and mixtures and combinations thereof.

The term “ambient conditions” are intended to mean the conditions of a room in which humans are present. For example, the ambient conditions of a clean room within the microelectronics industry can include a temperature of approximately 20° C., relative humidity of approximately 40%, illumination using fluorescent light (with or without yellow filters), no sunlight (from outdoors), and laminar air flow.

The term “barrier material” is intended to mean a material that substantially prevents the passage of contaminant of concern (e.g., air, oxygen, hydrogen, organic vapors, moisture) therethrough under the conditions in which the final device will likely be exposed to. Examples of materials useful to create barrier materials include, but are not limited to, glasses, ceramics, metals, metal oxides, metal nitrides, and combinations thereof.

The term “barrier sheet” is intended to mean a sheet or layer (which can have one or more sublayers or impreganted materials) of barrier material, created using any number of known techniques, including spinning, extruding, molding, hammer, casting, pressing, rolling, calendaring and combinations thereof. In one embodiment, the barrier sheet has permeability less than 10⁻² g/m²/24 hr/atm. The barrier sheet can be made of any material that has low permeability to gases and moisture, and is stable at the processing and operating temperatures to which it is exposed. Examples of materials that can be used for the barrier sheet include, but are not limited to, glasses, ceramics, metals, metal oxides, metal nitrides, and combinations thereof.

The term “bead” is intended to mean a particle of regular or irregular shape, and forming a discontinuous portion of a mixture.

The term “ceramic” is intended to mean an inorganic composition, other than glass, which can be heat treated in order to harden the inorganic composition during its manufacture or subsequent use by firing, calcining, sintering, or fusion of at least a portion of the inorganic material, fired clay compositions which form, e.g., porcelain or brick, and refractories.

The term “encapsulation assembly” is intended to mean one or more structures that can be used to cover, enclose, and at least forms part of a seal for one or more electronic components within an electrically active area of a substrate from ambient conditions. In conjunction with a substrate that includes one or more electronic components, the encapsulation assembly substantially protects a portion of such electronic component(s) from damage originating from a source external to the electronic device. In one embodiment, a lid, by itself, or in combination with one or more other objects, can form an encapsulation assembly.

The term “electronic active area” is intended to mean an area of a substrate, which from a plan view, is occupied by one or more circuits, one or more electronic components, or a combination thereof.

The term “electronic device” is intended to mean a collection of circuits, electronic components, or combinations thereof that collectively, when properly connected and supplied with the appropriate potential(s), performs a function. An electronic device may include or be part of a system. Examples of electronic devices include displays, sensor arrays, computer systems, avionics, automobiles, cellular phones, and many other consumer and industrial electronic products.

The term “engaged” is intended to mean the inserting, interlocking, meshing, placing, receiving, or any combination thereof of a first structure with respect to a second structure; the term “engaged” as used herein includes when elements are bound to one another using a substance or mixture.

The term “getter material” is intended to mean a material that is used to absorb, adsorb, or chemically tie up one or more undesired materials, such as water, oxygen, hydrogen, organic vapor and mixtures thereof. A getter material can be a solid, paste, liquid, or vapor. One type of gettering material can be used or mixtures or combinations or two or more materials.

The term “glass” is intended to mean an inorganic composition, which is principally silicon dioxide and may include one or more dopants to change is properties. For example, phosphorous-doped glass can be used to slow or substantially stop mobile ion migration therethrough as compared to undoped glass, and boron-doped glass can be used to lower the flow temperature of such material as compared to undoped glass.

The term “hermetic seal” is intended to mean a structure (or combination of structures) that substantially prevents the passage of therethrough at ambient conditions.

The term “lid” is intended to mean a structure that, by itself or in combination with one or more other objects, can be used to cover, enclose, and forms at least part of a seal for one or more electronic components within an electrically active area of a substrate from ambient conditions.

The term “metallic” is intended to mean containing one or more metals. For example, a metallic coating can include an elemental metal by itself, a clad, an alloy, a plurality of layers of any combination of an elemental metal, a clad, or an alloy, or any combination of the foregoing.

The term “perimeter” is intended to mean a closed curve bounding the central area of the barrier sheet. The perimeter is not limited to any particular geometric shape.

The term “organic electronic device” is intended to mean a device including one or more semiconductor layers or materials. Organic electronic devices include: (1) devices that convert electrical energy into radiation (e.g., a light-emitting diode, light emitting diode display, diode laser, or lighting panel), (2) devices that detect signals through electronic processes (e.g., photodetectors, photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The term “organic active layer” is intended to mean one or more organic layers, wherein at least one of the organic layers, by itself, or when in contact with a dissimilar material, is capable of forming a rectifying junction.

The term “rectifying junction” is intended to mean a junction within a semiconductor layer or a junction formed by an interface between a semiconductor layer and a dissimilar material, in which charge carriers of one type flow easier in one direction through the junction compared to the opposite direction. A pn junction is an example of a rectifying junction that can be used as a diode.

The term “structure” is intended to mean one or more patterned layers or members, which by itself or in combination with other patterned layer(s) or member(s), forms a unit that serves an intended purpose.

The term “substrate” is intended to mean a workpiece that can be either rigid or flexible and may be include one or more layers of one or more materials, which can include, but are not limited to, glass, polymer, metal or ceramic materials or combinations thereof.

The term “substantially continuous” is intended to mean that a structure extends without a break and forms a closed geometric element (e.g., triangle, rectangle, circle, loop, irregular shape, etc.). The term “transparent” is intended to mean the capability to transmit at least seventy percent of radiation at a wavelength or spectrum of wavelengths, e.g., visible light.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

### 2. Electronic Device Structures

Electronic devices that may benefit from the use of the present invention, include, but are not limited, light emitting diodes, organic displays, photovoltaic devices, field emission displays, plasma displays, microelectrical mechanical systems, photonic devices, and other electronic devices using integrated circuits (e.g., including, but not limited to accelerametors, gyroscopes, motion sensors). Thus, the size of the encapsulation assembly can be very small and will vary based on the type of electronic device with which it is being used.

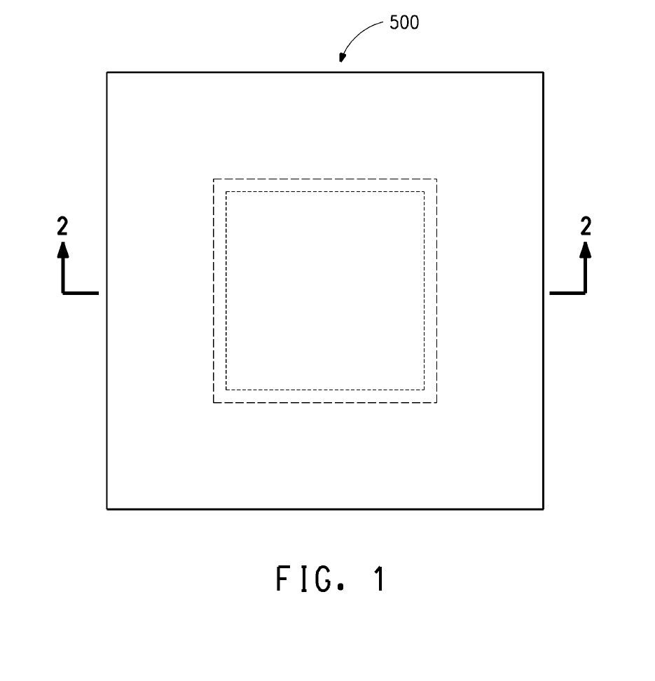

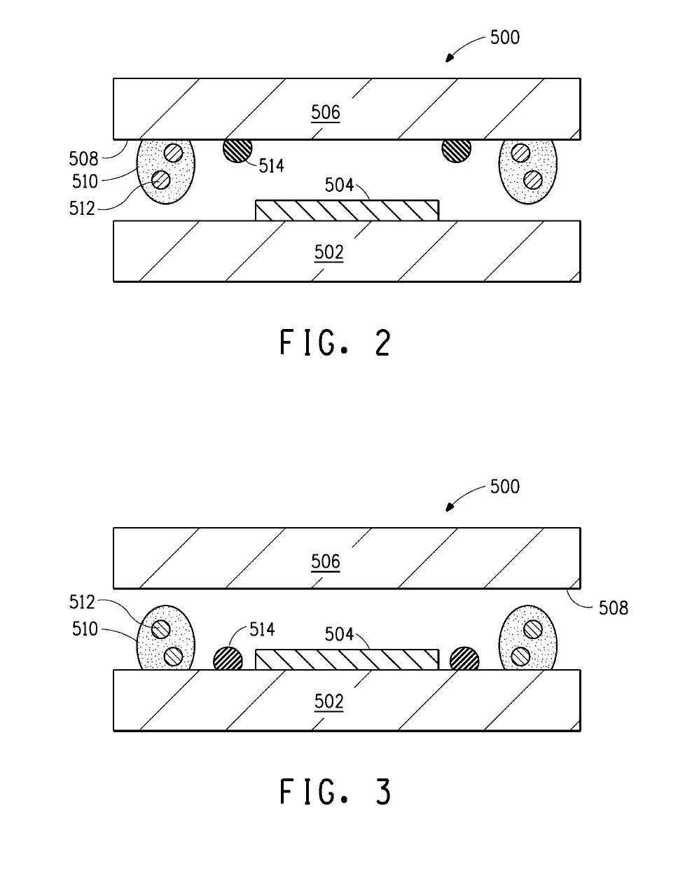

Referring to FIGS. 1 through FIG. 3, an embodiment of an electronic device is illustrated and is generally designated 500. In a particular embodiment, the electronic device is an organic electronic device, but the electronic device can be any electronic device that includes an interior space that requires sealing. As depicted, in FIGS. 1 through 3, the electronic device 500 includes a substrate 502. An electronic active area 504 is established on the substrate 502. Further, the electronic device 500 includes an encapsulation assembly 506. As indicated in FIGS. 2 and 3, the encapsulation assembly 506 includes a surface 508 and a barrier structure 510 that extends from the surface 508 (of a barrier sheet). A getter material 514 is formed inside the barrier structure 510. In one embodiment the getter material 514 can be applied via a screen printing method to form a continuous band to surround the electronic active area 504. In one embodiment, the barrier structure 510 (made of barrier material) is an adhesive material 510 in combination with a discreet material 512. In another embodiment the barrier structure 510 is an epoxy adhesive in combination with glass beads as the discreet material 512. The barrier structure 510 is deposited or otherwise formed on the surface of the encapsulation assembly 506, FIG. 2. In another embodiment, the barrier structure 510 is deposited or otherwise formed on the surface of the substrate 502, FIG. 3. Barrier structure 510 has a thickness (the dimension from which it extends from the barrier sheet at its peak extension and this thickness may be a uniform thickness or may varying depending on the type of barrier sheet, how the barrier sheet and barrier structure are manufactured and the type of device substrate to which the encapsulation assembly will be finally attached.) For example, the barrier structure 510 may be created by first depositing the barrier material in one physical form (such as a paste or fluid) and then treating the material further to create the barrier structure, or it may be created for example, by other techniques such that the barrier structure is created separately from the barrier sheet or where the barrier sheet 508 and the barrier structure 510 are manufactured together. The dimension of the discreet material 512 defines the lower limit of the distance between the encapsulation assembly 506 and the substrate 502. In one embodiment the distance can be up to 3 mm, in another embodiment the distance can be 1 mm or less.

In another particular embodiment, the getter material can be in the form of discontinuous strips (not shown) located between the barrier structure 510 and the electronic active area 504.

From these Figures, it can be appreciated that the barrier structures can be located in location on the barrier sheet so as to be outside of the device active area when in use. Only in certain embodiments is the barrier structure located interior of the outer edge of the device substrate. No spacers are needed to elevate the encapsulation assembly off the surface of the device, as the thickness of the discreet material 512 is sufficient to maintain spacing between the encapsulation assembly 506 and electronic active area 504.

In each of the embodiments described herein, the seal established between the encapsulation assembly and the device substrate substantially reduces permeation of liquid or air through the seal, over encapsulation techniques using adhesive as the primary sealing element while improving manufacturing options over sealing elements where the barrier structure is fused or sintered to both the barrier surface and the device substrate.

Moreover, in the embodiments in which the thickness of the barrier structure of the encapsulation assembly and the device substrate is reduced to 3 millimeters or less, the permeation of containments has been found to be acceptable for many applications, and selection of the adhesive can be made based primarily on factors other than contaminant permeation rate through the adhesive, such as adhesive qualities relating to adhesive strength, UV durability, environmental issues, price, and ease of application to name a few.

In one embodiment, the barrier structure is made from a barrier material has a permeability of less than 10⁻² g/m²/24 hr/atm. In another embodiment, the barrier structure has permeability less than 10⁻³ g/m²/24 hr/atm. In one embodiment, the barrier structure has permeability to gases and moisture of less than about 10⁻⁶ g/m²/24 hr/atm at room temperatures. In one embodiment, the barrier material is inorganic.

In one embodiment the discreet material is made from a material that is selected from glasses, ceramics, metals, metal oxides, metal nitrides, and combinations thereof. In one embodiment, the discreet material comprises a non-hermetic base with a coating of barrier material. In one embodiment the barrier structure has a thickness slightly in excess of the electronically active display components of the device.

In one embodiment, the discreet material is glass and is applied as a glass frit composition. As used herein, the term “glass frit composition” is intended to mean a composition comprising glass powder dispersed in an organic medium. After the glass frit composition is applied to the barrier sheet, it is solidified and densified to form a glass structure. As used herein, the term “solidifying” means drying sufficiently to stabilize the deposited frit composition, such as to prevent unacceptable spreading of the composition to undesired locations or damage caused by storing the surfaces containing solidified frit composition (e.g., by stacking). The term “densifying” means heating or reheating the composition so as to drive off substantially all volatiles, including, but not limited to the liquid medium and to cause fusing of the glass powder particles and adherence to the surface of the barrier sheet to which it has been applied. Densification can be carried out in an oxidizing or inert atmosphere, such as air, nitrogen or argon, at a temperature and for a time sufficient to volatilize (burn-out) the organic material in the layers of the assemblage and to sinter any glass-containing material in the layers thus, densifying the thick film layer. The permeability of the glass decreases as it is densified. In one embodiment, the glass is fully densified. In one embodiment, densification is determined by the transparency of fired glass, with complete transparency indicating sufficient densification.

Glass frit compositions are well known and many commercial materials are available. In one embodiment, the glass powder comprises, based on weight %, 1-50% SiO₂, 0-80% B₂O₃, 0-90% Bi₂O₃, 0-90% PbO, 0-90% P₂O₅, 0-60% Li₂O, 0-30% Al₂O₃, 0-10% K₂O, 0-10% Na₂O, and 0-30% MO where M is selected from Ba, Sr, Ca, Zn, Cu, Mg and mixtures thereof. The glasses may contain several other oxide constituents. For instance ZrO₂ and GeO₂ may be partially incorporated into the glass structure.

High contents of Pb, Bi or P in glass provide a very low softening point that allow glass frit compositions to densify below 650° C. These glasses are not crystallized during densification, since the elements tend to provide good stability of glass and a high solid solubility for other glass elements.

Other glass modifiers or additives may be added to modify glass properties for better compatibility with a given substrate. For example, the temperature coefficient of expansion (“TCE”) of the glass may be controlled by the relative content of other glass components in the low-softening temperature glasses.

Additional examples of glass powders that are suitable include those that comprise at least one of PbO, Al₂O₃, SiO₂, B₂O₃, ZnO, Bi₂O₃, Na₂O, Li₂O, P₂O₅, NaF and CdO, and MO where O is oxygen and M is selected from Ba, Sr, PB, Ca, Zn, Cu, Mg, and mixtures thereof. For example, the glass can comprise 10-90 wt % PbO, 0-20 wt % Al₂O₃, 0-40 wt % SiO₂, 0-15 wt % B₂O₃, 0-15 wt % ZnO, 0-85 wt % Bi₂O₃, 0-10 wt % Na₂O, 0-5 wt % Li₂O, 0-45 wt %, P₂O₅, 0-20 wt % NaF, and 0-10 wt % CdO. The glass can comprise: 0-15 wt % PbO, 0-5 wt % Al₂O₃, 0-20 wt % SiO₂, 0-15 wt % B₂O₃, 0-15 wt % ZnO, 65-85 wt % Bi₂O₃, 0-10 wt % Na₂O, 0-5 wt % Li₂O, 0-29 wt % P₂O₅, 0-20 wt % NaF, and 0-10 wt % CdO. Glass can be ground to provide powder-sized particles (in one embodiment, the powder size is from 2-6 microns) in a ball mill.

The glasses described herein are produced by conventional glass making techniques. For example, the glasses may be prepared as follows. For preparation of 500-2000 gram quantities of glass frit, the ingredients were weighed then mixed in the desired proportions and heated in a bottom-loading furnace to form a melt in platinum alloy crucibles. Heating temperatures depend on the materials and can be conducted to a peak temperature (1100-1400° C.) and for a time such that the melt becomes entirely liquid and homogeneous. The glass melts were quenched by a counter rotating stainless steel roller to form a 10-20 mil thick platelet of glass. The resulting glass platelet was then milled to form a powder with its 50% volume distribution set between 1-5 microns, though the particle size can vary depending on the final application of the encapsulation assembly. The glass powders were then formulated with filler and organic medium into a thick film composition (or “paste”). The glass powder is present in the glass frit composition in the amount of about 5 to about 76 wt. %, based on total composition comprising, glass and organic medium. In one embodiment, the organic medium contains water. In one embodiment, the organic medium includes an ester alcohol.

The organic medium in which the glass is dispersed is comprised of the organic polymeric binder which is dissolved in a volatile organic solvent and, optionally, other dissolved materials such as plasticizers, release agents, dispersing agents, stripping agents, antifoaming agents and wetting agents.

The solids are typically mixed with an organic medium by mechanical mixing to form a pastelike composition, called “pastes”, having suitable consistency and rheology for printing. A wide variety of liquids can be used as organic medium and water may be included in the organic medium. The organic medium must be one in which the solids are dispersible with an adequate degree of stability. The rheological properties of the medium must be such that they lend good application properties to the composition. Such properties include: dispersion of solids with an adequate degree of stability, good application of composition, appropriate viscosity, thixotropy, appropriate wettability of the substrate and the solids, a good drying rate, good firing properties, and a dried film strength sufficient to withstand rough handling. In one embodiment the organic medium comprises a suitable polymer and one or more solvent.

In certain embodiments, the polymer used in the organic medium is selected from the group consisting of ethyl cellulose, ethylhydroxyethyl cellulose, wood rosin, mixtures of ethyl cellulose and phenolic resins, polymethacrylates of lower alcohols, and monobutyl ether of ethylene glycol monoacetate or mixtures thereof.

The most widely used solvents found in thick film compositions are ethyl acetate, and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters, including isobutyal alcohol and 2-ethyl hexanyl. In addition, volatile liquids for promoting rapid hardening after application on the substrate can be included in the vehicle. In one embodiment, medium is selected from ethylcellulose and β-terpineol. Various combinations of these and other solvents are formulated to obtain the viscosity and volatility requirements desired. Water may be used as well as part of the organic medium.

The ratio of organic medium in the thick film composition to the glass frit solids in the dispersion is dependent on the method of applying the paste and the kind of organic medium used, and it can vary. Usually, the dispersion will contain 50-80 wt. % of glass frit and 20-50 wt. % of vehicle in order to obtain good coating. Within these limits, it is desirable to use the least possible amount of binder vis-à-vis solids in order to reduce the amount of organics which must be removed by pyrolysis and to obtain better particle packing which gives reduced shrinkage upon firing. The content of the organic medium is selected to provide suitable consistency and rheology for casting, printing, such as screen printing or ink-jet printing, molding, stencil printing, extruding, or coating by spraying, brushing, syringe-dispensing, doctor blading, and the like.

In the case of screen-printing, the screen mesh size controls the thickness of deposited material. In one embodiment, the screen used in screen printing has a mesh size of from 25 to 600; in one embodiment, the mesh size is from 50 to 500; in one embodiment, the mesh size is 200-350; in another embodiment the mesh size is from 200 to 275; and in another embodiment the mesh size is from 275 to 350. For reference purposes mesh sizes can have varying wire sizes that can alter the film formed during the printing process. A smaller mesh size results in thicker deposition as does a large screen wire size. For reference purposes, the following table is provided.

Mean effective media size

| Media No. Material | mm | in. | Screen mesh size |
|---|---|---|---|
| 8 crushed granite | 1.50 | 0.059 | 100-140 |
| 11 crushed granite | 0.78 | 0.031 | 140-200 |
| 16 crushed silica | 0.66 | 0.026 | 140-200 |
| 20 crushed silica | 0.46 | 0.018 | 200-230 |
| 30 crushed silica | 0.34 | 0.013 | 230-400 |

The deposited glass frit composition is dried to remove volatile organic medium and solidify. Solidification can be carried out by any conventional means. In one embodiment, the composition is heated in an oven at about 100-120° C., though the temperature may vary depending on the softening point of the glass used and the type of getter material used, (if one is used). Furthermore, other techniques may be used to heat the glass frit without substantially heating the barrier sheet. The solidified material is then densified as desired. For example, densification can be carried out by any conventional means and may be done as part of one heating cycle immediately after the solidification heating or may be accomplished two or more separate heating cycles, with or without some degree of cooling between heatings. In some embodiments, the glass frit composition is densified when heated at 400-650° C. in a standard thick film conveyor belt furnace or in a box furnace with a programmed heating cycle forming a fired article.

When glass is used to create the discreet material, the final thickness of the barrier structure formed from the glass frit composition can vary depending on the method of deposition, content of glass and solid % in the composition.

In one embodiment, the discreet material is a metal. Almost all metals have the requisite low permeability to gases and moisture. Any metal can then be used, so long as it is stable to the atmosphere and adheres to the barrier sheet. In one embodiment, the metal is selected from Groups 3-13 in the Periodic Table. The IUPAC number system is used throughout, where the groups from the Periodic Table are numbered from left to right as 1-18 (CRC Handbook of Chemistry and Physics, 81^{st} Edition, 2000). In one embodiment, the metal is selected from Al, Zn, In, Sn, Cr, Ni, and combinations thereof.

The metal can be applied by any conventional deposition technique. In one embodiment, the metal is applied by vapor deposition through a mask. In one embodiment, the metal is applied by sputtering.

The barrier material can be applied as one layer, or it can be applied as more than one layer to achieve the desired thickness and geometry.

In one embodiment, the barrier structure is created by using a suitable barrier material applied as a continuous perimeter of the barrier sheet or the seal can be created by varying the location, staggering as necessary and arrange of the hermetic material to achieve the desired hermetic seal. Although, it is three-dimensional, the perimeter appears as a line of material around the outer part of the major surface of the barrier sheet, or can be placed to merely be around the perimeter of the active area of the device. It has no gaps or openings and defines the area of the barrier sheet that will be sealed to the substrate of the electronic device.

In one embodiment, the barrier sheet comprises glass. Most glasses have a permeability of less than about 10⁻¹⁰ g/m²/24 hr/atm. In one embodiment, the glass is selected from borosilicate glasses and soda lime glass. The barrier sheet is substantially planar. In one embodiment, the barrier sheet is rectangular. In one embodiment, the barrier sheet has a thickness in the range of 0.1 mm to 5.0 mm.

In one embodiment, as shown in FIG. 1, the perimeter 2 has a rectangular shape around the outer edge of barrier sheet 1, as in a window frame. In one embodiment, the perimeter of barrier material has a circular shape. In one embodiment, the perimeter of barrier material has an irregular shape adapted to complement the particular substrate of the electronic device.

The barrier structure itself can have different geometries. The edges can be straight, tapered, or curved. The top can be flat or beveled. The barrier structure can have any width and thickness that will provide protection from contaminants such as hydrogen and oxygen gases and moisture and the requirements of the device or other application on which the encapsulation assembly is to be used. In one embodiment, the barrier structure has a width in the range of 10 to 5000 microns and a thickness in the range of 5 to 500 microns. In one embodiment, the barrier structure is about 7 microns thick. In one embodiment, the barrier structure has a width in the range of 500 to 2000 microns and a thickness in the range of 50 to 100 microns. The thickness may be achieved through the use of more than one discreet material.

In one embodiment, two or more continuous deposited patterns (e.g., around the perimeter of the active area of the device) of the barrier structure material are applied to form two or more structures on the barrier sheet. The materials used to create the structures can be the same or different and the shape and dimensions of the structures can be the same or different. In one embodiment, the structures from the barrier sheet are the made from the same materials and have the same shape.

To use the encapsulation assembly, at least one adhesive is used in the barrier structure (s), barrier sheet, substrate of the electronic device, or any combination of these. If the barrier structure containing the adhesive is applied to the substrate of the electronic device only, then it must be deposited in a manner so as to so that the substrate and the barrier sheet can be coupled together. In one embodiment, the barrier structure is applied to the bottom and outer edge of the barrier sheet. In another embodiment, the barrier structure is applied to the substrate of the electronic device. Selection of the adhesive in the barrier structure is made by consideration of whether it will adhere the barrier structure to the device substrate, or if the barrier structure is on the device substrate, then the adhesive must bond the barrier structure to the barrier sheet.

Advantages of certain embodiments can be appreciated. That is, though use of a properly designed barrier structure, it is possible to use a smaller amount of adhesive than would otherwise be necessary. In addition, it is possible to make a selection of one or more adhesives from a larger number of adhesive compositions because of the smaller area where the adhesive contaminant permeation rate is relevant.

In one embodiment, when glass discreet materials are used, the adhesive is a UV curable epoxy. Such materials are well known and widely available. Other adhesive materials can be used so long as they have sufficient adhesive and mechanical strength.

In one embodiment, provided is an electronic device having the barrier sheet with a barrier structure encapsulation assembly adhered thereto by application of a suitable adhesive to the substrate of the electronic device. The other properties of the substrate are governed primarily by the requirements of the electronic device. For example, for organic light emitting diode display devices, the substrate is usually transparent so that it transmits the light generated. The substrate can be made of materials which can be rigid or flexible and includes, for example, glass, ceramic, metals, polymeric films, and combinations thereof. In one embodiment, the substrate comprises glass. In one embodiment, the substrate is flexible. In one embodiment, the substrate comprises polymeric films.

In one embodiment, to use the encapsulation assembly is placed over the substrate of the electronic device. This assembly step can be done in normal ambient conditions or may be done under controlled conditions including reduced pressure or inert atmospheres as desired or required by the electronic device to which it is applied.

In one embodiment, the barrier sheet also has a getter material applied thereto. In one embodiment, the getter material is deposited on the surface of the barrier sheet so as to be between the barrier structure and the active area of the device when assembly of the device is completed. Optional additional locations of gettering materials may be deposited as desired.

The getter material can be in the form of a ribbon, band, frit, pellet, wafer or a film. In one embodiment, a getter material is applied to the barrier sheet as part of a thick film paste composition, as disclosed in co-pending applications U.S. Ser. No. 10/712,670 and U.S. Provisional No. 60/519,139. In one embodiment, at least a portion of the getter material is deposited outside of the device active area when the encapsulation assembly is used with the device. In this embodiment, deposition of a sufficient amount of getter material to create a thickness larger than the final thickness of the active area of the device.

In an embodiment where the getter material is deposited on the barrier sheet, the getter material can be optionally activated in a separate step from the manufacture of the encapsulation assembly itself and before the encapsulation assembly is applied to the device. Thusly, the encapsulation assembly can be stored for long periods of time under ordinary storage conditions, as the getter material may be activated at a later time when the encapsulation assembly is used in the manufacture of the device. In such embodiments, once the getter material is activated, the encapsulation assembly can be maintained in a controlled environment and in such a manner so that the getter material's performance capacity is not consumed prematurely.

In one embodiment, improved device lifetime have been observed with an encapsulation assembly shown in FIG. 3 is used to encapsulate an organic light emitting diode display device.

### EXAMPLES

FIG. 4 notes display samples made with various amounts of getter material within the encapsulation assembly. The pixel emitting area (1.000=100%) after storage testing at 60 degrees C. and 90 percent relative humidity is indicated by the lines within each test group. The test indicating full getter area shows a near 100% pixel emitting area after completion of the storage test. These tests indicated a 35 micron thick getter, occupying the entire active area of an OLED display, will achieve 1000 hours of 60×90 storage testing with little to no pixel loss.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. An encapsulation assembly for an electronic device, the electronic device having a substrate and an active area, the encapsulation assembly comprising:
a generally planar barrier sheet; and
a barrier structure comprising an adhesive material and a discreet material, wherein:
the barrier structure is configured so as to substantially hermetically seal the generally planar barrier sheet to the electronic device when in use thereon; and wherein the generally planar barrier sheet is configured so as to avoid direct contact with the electronic device substrate when the electronic device is bonded to the encapsulation assembly.

2. The encapsulation assembly of claim 1, wherein the adhesive material comprises an organic or an inorganic adhesive material.

3. The encapsulation assembly of claim 2, wherein the organic adhesive material is selected from the group consisting of an ethylene vinyl acetate, phenoylic resins, rubber (natural and synthetic), carboxylic polymers, polyamides, polyimides, styrene-butadiene, silicone, epoxy, urethane, acrylic, isocyanate, polyvinyl acetates, polyvinyl alcohols, polybenzimidazole, cyanoacrylate and mixtures and combinations thereof.

4. The encapsulation assembly of claim 1, wherein the discreet material is selected from the group consisting of glass, ceramic, metallic materials or combination thereof.

5. The encapsulation assembly of claim 4, wherein the discreet material is glass.

6. The encapsulation assembly of clam 5, wherein the electronic device is an organic electronic device.

7. The encapsulation assembly of clam 6, wherein the organic electronic device is an OLED device.

8. The encapsulation assembly of claim 1, further comprising a getter material deposited on the barrier sheet and configured so as to be outside of the active area of the electronic device, yet exposed to the device active area of the electronic device when the electronic device is bonded to the encapsulation assembly.

9. The encapsulation assembly of claim 8, wherein the getter material comprises a substantially continuous band.

10. The encapsulation assembly of claim 1, wherein the encapsulation assembly is transparent.

11. The assembly of claim 1, wherein the barrier sheet and the barrier structure are constructed as one element.

12. An electronic device comprising:
a substrate comprising an electrically active area of an organic electronic device;
a lid covering the electrically active area, wherein the lid comprises a substantially planar barrier surface that faces the device substrate; and
a structure comprising an epoxy adhesive and glass beads, wherein the structure attaches the barrier surface of the lid to the device substrate, wherein the barrier surface is no more than 3 mm away from substrate.

13. The organic electronic device of claim 12, the barrier surface further comprises a getter material exposed to the electronic active area.

14. The organic electronic device of claim 12, the device substrate further comprises a getter material exposed to the electronic active area.

15. The organic electronic device of claim 13, wherein the organic electronic device is an OLED device.

16. An encapsulation assembly for an electronic device, the electronic device having a substrate and a barrier structure extending from the substrate and outside of an active area, the encapsulation assembly comprising:
a barrier sheet having a substantially flat surface and the barrier structure comprising an epoxy adhesive and glass beads;
a getter material outside of the active area and inside of the barrier structure; and
wherein the barrier sheet is configured to engage with the barrier structure on the device substrate.

17. An organic electronic device comprising the encapsulation assembly of claim 15.

18. The organic electronic device of claim 17, wherein the organic electronic device is an OLED device.

19. The organic electronic device of claim 18, wherein the barrier sheet engages with the device substrate to maintain a distance of less than 2 mm.

20. The organic electronic device of claim 19, wherein the distance is less than 1 mm.
